(19) United States
(12) Patent Application Publication
(10) Pub. No.: US 2025/0030388 A1
(43) Pub. Date: Jan. 23, 2025

(54) POWER COMBINER FOR POWER AMPLIFIER

(71) Applicant: Telefonaktiebolaget LM Ericsson (publ), Stockholm (SE)

(72) Inventors: Mingquan BAO, Västra Frölunda (SE); David GUSTAFSSON, Sävedalen (SE)

(21) Appl. No.: 18/713,837

(22) PCT Filed: Dec. 2, 2021
(86) PCT No.: PCT/SE2021/051193

§ 371 Date: May 28, 2024

(51) Int. Cl. H03F 3/24

(52) U.S. Cl. CPC H03F 3/245; H03F 2200/451

(57) ABSTRACT

A power combiner for combing output powers from multiple power cells included in a power amplifier is disclosed. The power combiner includes a current combiner configured to combine output currents from at least two power cells comprised in the power amplifier and a voltage combiner configured to combine output voltages from at least two power cells included in the power amplifier. The voltage combiner and current combiner are connected in cascade.

### TECHNICAL FIELD

Embodiments herein relate to a power combiner for a power amplifier. Further, the embodiments relate to a power amplifier comprising the power combiner and an electronic device comprising the power amplifier.

### BACKGROUND

In a wireless communication system, a transmitter employs power amplifiers (PA) to increase radio frequency (RF) signal power before transmission. A PA is expected to amplify input signals linearly and generate output signals with larger power but with identical characteristics to the input signals.

The 5^{th} generation (5G) new radio (NR) operates at frequencies either below 6 GHz or at frequencies from 24 GHz to 41 GHz. In 6G wireless communication networks, sub-terahertz bands, e.g., 114 GHz to 300 GHZ, are expected to become practical for use in cellular systems in specific scenarios, as well as in integrated access and backhaul networks.

A large output power transmitter is usually desired for 5G/6G NR. However, on the other hand, transistor's gain and output power decreases as frequency increases. Therefore, it is necessary to combine several power cells' outputs, to realize a large output power. The power combining technique becomes critical, which determines the power amplifier's output power and frequency bandwidth.

The most common used power combining techniques are current combining and voltage combining.

For the current combining techniques, a tree-structure power combiner is widely applied in narrowband designs, but it is less suitable when targeting large bandwidths. In the latter case various types of distributed amplifiers has a clear advantage. A basic architecture of a distributed PA is shown in Error! Reference source not found. (a) disclosed in G. Nikandish, R. B. Staszewski and A. Zhu, “The revolution of distributed amplifier: from vacuum tubes to modern CMOS and GaN ICs”, IEEE Microwave Magazine, vol. 19, no. 4, pp. 66-83, June 2018, and C. F. Campbell, “Evolution of the nonuniform distributed power amplifier”, IEEE Microwave Magazine, Vol. 20, No. 1, pp. 18-27, 2019. The drains of the transistors are connected with transmission lines (TLs), and the currents from drains are combined by those TLs. The parasitic capacitance of the transistors and the TLs form a so-called artificial transmission line with Ld and Cd sections, as shown in Error! Reference source not found. (b), where an equivalent circuit based on lumped-element artificial transmission lines for the distributed PA is shown. Due to the parasitic capacitors are synchronized in TLs, a broadband PA is realized. The gates of the transistors are connected by TLs also, the input signal is applied at one terminal of the gate TLs.

To avoid that output power gets dissipated at resistor Z_{od}, and to equalize the load of transistors, the resistor Z_{od} can be removed by letting the transmission lines have different width, thus, having different characteristic impedance. Such kind of amplifier is called a nonuniform distributed power amplifier as shown in FIG. 2 disclosed in the same articles listed above.

It should be noted that, if the transistors have the same size, the load impedance of the PA is equal to

$$\frac{{Z}_{od}}{n}$$

which decrease will the number of power cells, n, where Z_{od} is the characteristic impedance of the first TL.

A transformer-based current combiner is shown in FIG. 3, disclosed in Andrea Bevilacqua, “Fundamentals of Integrated Transformers: From Principles to Applications”, IEEE SOLID-STATE CIRCUITS MAGAZINE, Vol. 12, no. 4, November 2020, where the secondary windings are connected in parallel. The currents from each transformer are added at the load R_{L} of PA.

A voltage combiner may consist of coupled transmission lines, as shown in FIG. 4, disclosed in A. M. Niknejad, et. al. “Integrated circuit transmission-line transformer power combiner for millimetre-wave applications”, Electronics Letters, Vol: 43, no: 5, 2007, and M. G. Anderson, et. al. “Ultralow-Power Radio Frequency Beamformer Using Transmission-Line Transformers and Tunable Passives”, IEEE MICROWAVE AND WIRELESS COMPONENTS LETTERS, VOL. 29, NO. 2, February 2019. If the transistor's output current is equal, the current through the load is the same as the current delivered by a single transistor, I₀, while the voltage at the load is summary of voltage swings of all transistors, nV₀. Similarly, transformers connected in series can also form a voltage power combiner, as shown in FIG. 5, disclosed in the same article as FIG. 3.

It should be pointed out that the load impedance of the PA, i.e., the load impedance of “voltage combiner” is

$$\frac{{nV}_{0}}{{I}_{0}}$$

which increases with the number of power cell.

In H. Wang, et. al., “MM-wave integration and combinations” IEEE Microw. Mag., vol. 13, no. 5, pp. 49-57, July 2012, Jiang An Han, et. al. “A 26.8 dB Gain 19.7 dBm CMOS Power Amplifier Using 4-way Hybrid Coupling Combiner”, IEEE MICROWAVE AND WIRELESS COMPONENTS LETTERS, VOL. 25, NO. 1, January 2015, and Domenico Pepe, et. al. “1.29-W/mm2 23-dBm 66-GHz Power Amplifier in 55-nm SiGe BiCMOS With In-Line Coplanar Transformer Power Splitters and Combiner”, IEEE MICROWAVE AND WIRELESS COMPONENTS LETTERS, VOL. 27, NO. 12, December 2017, a hybrid of current/voltage combiner is presented, as shown in FIG. 6. As shown in FIG. 6(a), two transformers T1 and T2 are connected in series for voltage combining, and two transformers T3 and T4 are connected in series for voltage combining, and then, two series connected transforms T1/T2 and T3/T4 are connected in parallel for current combining. FIG. 6(b) shows the transformers in the hybrid of current/voltage combiner implemented by differential spiral inductors.

There are some problems with the existing combining techniques. For examples, the tree structure combiner has a relative narrow bandwidth, comparing to the “artificial TL” combiner. As shown in FIG. 2, in a non-uniform distributed amplifier, the widths of the transmission lines increase from left to right, e.g. requiring a transmission line width larger than 300 μm in e.g. a 60 nm Gallium nitride (GaN) semiconductor process. This wide transmission line occupies a large chip area and is difficult to be folded. Even though a wide TL can be replaced by a relative narrow TL with shunt capacitors, the equivalent TL would have a narrower frequency bandwidth and a high loss, compared to the TL without shunt capacitors.

Further, an impedance transformation network (ITN) is needed for impedance matching and the impedance transformation ratio is the load impedance R_{L} of the power combiner to 50Ω load of a power amplifier. In high power application, where R_{L}=Z_{od}/n<<50Ω, multi cascaded TLs have to be used, which results in large area and losses.

### SUMMARY

Therefore, it is an object of embodiments herein to provide a power combiner with improved performance.

According to one aspect of embodiments herein, the object is achieved by a power combiner for combing output powers from multiple power cells comprised in a power amplifier. The power combiner comprises a current combiner configured to combine output currents from at least two power cells comprised in the power amplifier and a voltage combiner configured to combine output voltages from at least two power cells comprised in the power amplifier. The voltage combiner and current combiner are connected in cascade.

According to some embodiments herein, an input terminal of the voltage combiner may be connected to an output of the current combiner and an output terminal of the voltage combiner may be connected to a load of the power amplifier, R_{L}; or an input terminal of the current combiner may be connected to an output of the voltage combiner and an output terminal of the current combiner may be connected to a load of the power amplifier.

According to some embodiments herein, the current combiner may comprise one or more transmission lines connected in series and output terminals of the at least two power cells for current combining are connected to the transmission lines.

According to some embodiments herein, the voltage combiner may comprise one or more transformer or coupled transmission lines and each transformer or coupled transmission line comprises a primary transmission line having a first input terminal and a first output terminal and a secondary transmission line having a second input terminal and a second output terminal.

According to one aspect of embodiments herein, the object is achieved by a power amplifier comprising the power combiner described above and an electronic device comprising the power amplifier. The electronic device may be a transmitter, a transceiver, a base station, a mobile device, a user equipment, a radar, a wireless communication device for a communication system.

The power combiner according to embodiments herein comprises a current combiner and a voltage combiner and can solve the problem of a distributed power amplifier. Namely, the number of power cells could be limited by the difficulty of implementation of a transmission line with extra low characteristic impedance. While the voltage combiner needs not TLs with low characteristic impedances.

The current combiner and voltage combiner are connected in cascade. That is one terminal of the voltage combiner may be connected to the current combiner, and another terminal may be connected to the load of a power amplifier. In this way, the voltage combiner acts as an upward impedance transformer and converts up the output impedance of the current combiner, so an ITN can be removed if the output impedance of the voltage combiner reaches 50Ω.

When the output impedance of the voltage combiner does not reach 50Ω, an ITN is still needed. However, the voltage combiner has benefits of boosting output impedance so the impedance transformation ratio to 50Ω is reduced. Consequently, the number of TLs to build an ITN is reduced, thus, the loss of the ITN can be reduced.

The power combiner according to embodiments herein has advantages from both a current combiner and a voltage combiner, such as minimized combiner loss, broad bandwidth etc.

Therefore, embodiments herein provide a power combiner with improved performance.

### BRIEF DESCRIPTION OF THE DRAWINGS

Examples of embodiments herein are described in more detail with reference to attached drawings in which:

FIG. 1 (a) shows a basic architecture of a distributed amplifier according to prior art; (b) is an equivalent circuit of the distributed amplifier based on lumped-element artificial transmission lines;

FIG. 2 shows a schematic of a nonuniform distributed power amplifier according to prior art;

FIG. 3 shows a transformer-based current combiner according to prior art;

FIG. 4 shows a voltage combiner consists of coupled transmission lines according to prior art;

FIG. 5 shows a transformer-based power combiner according to prior art;

FIG. 6 shows a hybrid current/voltage combiner according to prior art;

FIG. 7 shows currents and voltages along drain transmission lines for a distributed power amplifier;

FIG. 8 (a) and (b) are block diagrams showing a power amplifier with a power combiner according to embodiments herein;

FIG. 9 is a schematic block diagram showing a non-uniform distributed amplifier with a power combiner according to an example embodiment herein;

FIG. 10 is a schematic block diagram showing an amplifier with a power combiner according to another example embodiment herein;

FIG. 11 is a schematic block diagram showing an amplifier with a power combiner according to another embodiment herein;

FIG. 12 is a schematic block diagram showing an amplifier with a power combiner according to another embodiment herein;

FIG. 13 is a schematic block diagram showing a conventional non-uniform distributed amplifier; and

FIG. 14 is a block diagram illustrating an electronic device/apparatus in which embodiments herein may be implemented.

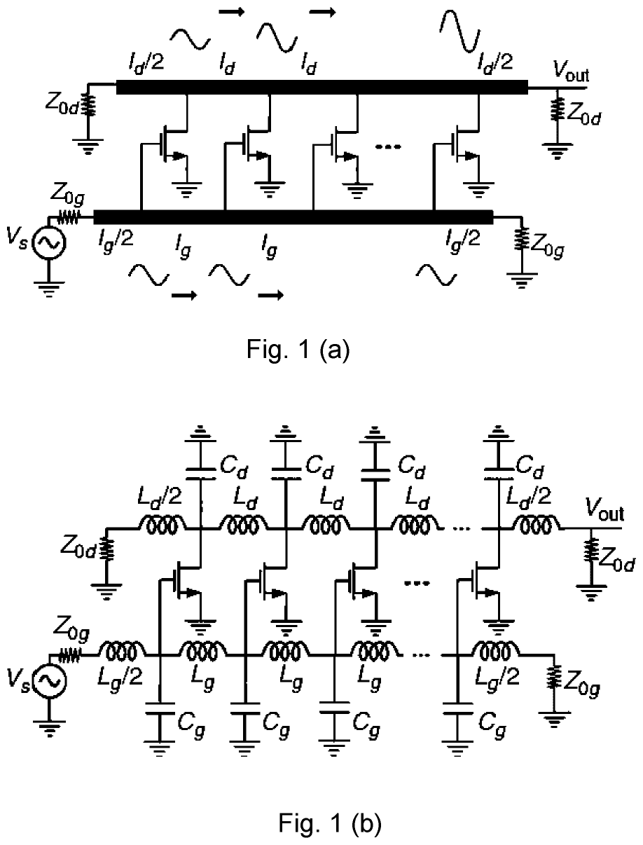

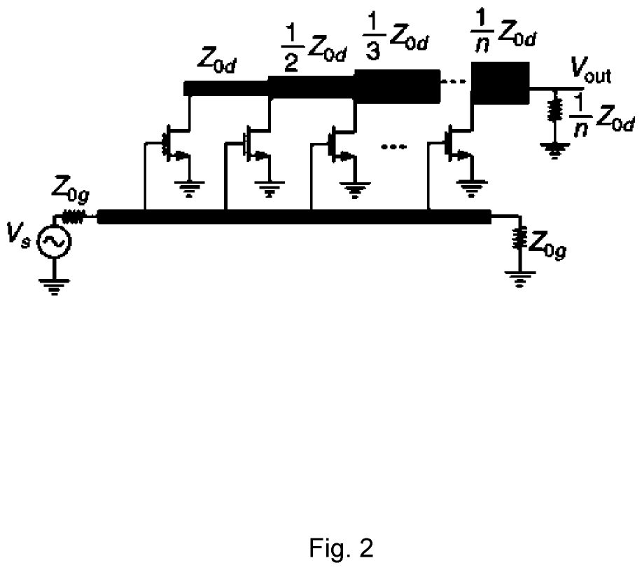

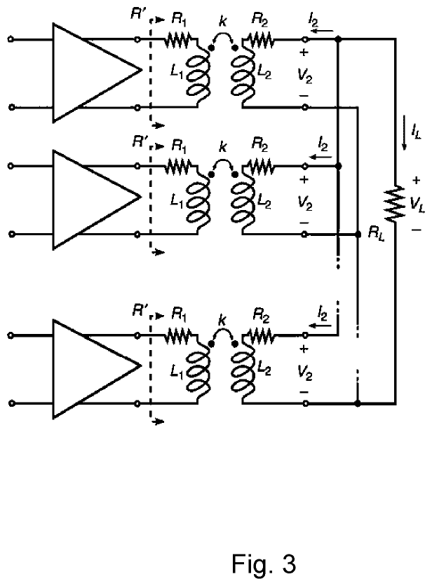

### DETAILED DESCRIPTION

As part of developing embodiments herein, the principle of current combining and voltage combining is first described and analysed.

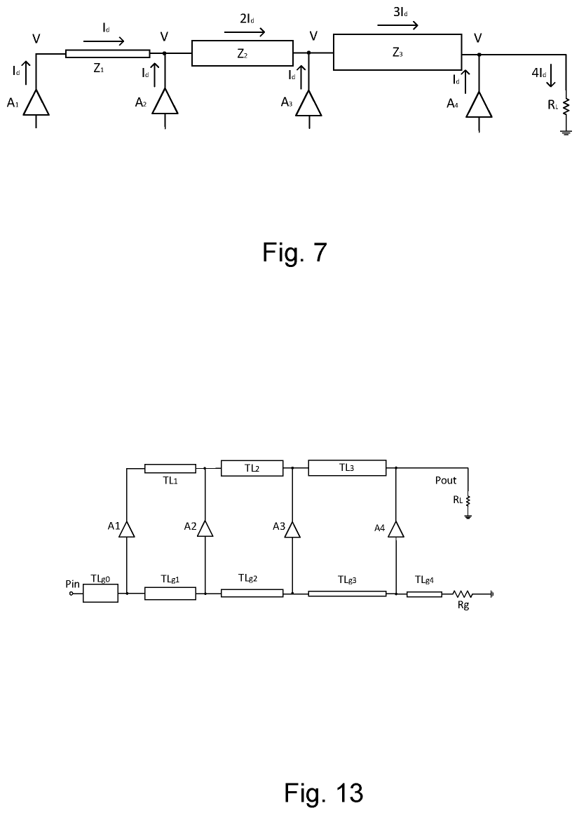

FIG. 7 shows a non-uniform distributed amplifier, where output currents from power cells Aᵢ, i=1,2,3 . . . , are combined by TLs. The voltage does not change significantly along the TLs, the currents from each power cells are added at the load impedance R_{L}. Such kind of combiner is called “current combining”. For simplicity, it is assumed that all power cells or transistors have the same size, and deliver the same alternating current (AC), Id. The output impedances of the transistors are matched to

$${R}_{opt} = \frac{V}{{I}_{d}} . \qquad ( 1 )$$

At the maximum output power, all transistors are switched “on”, the currents and the voltages along the drain transmission lines are shown in FIG. 7.

The transmission lines have the characteristic impedances:

$${Z}_{1} = \frac{V}{{I}_{d}} , {Z}_{2} = \frac{V}{2 {I}_{d}} , {Z}_{3} , \frac{V}{3 {I}_{d}} \qquad ( 2 )$$

Thus,

$${Z}_{1} = {R}_{opt} , {Z}_{2} = \frac{1}{2} {R}_{opt} , and {Z}_{3} = \frac{1}{3} {R}_{opt} .$$

Since the current through the load resistor R_{L} is 4l_{d}, then

$${R}_{L} = \frac{1}{4} {R}_{opt} .$$

If extending the number of the power cells from 4 to n, it can be found that:

The characteristic impedance of the transmission line at most left side, i.e. at beginning of the series connected transmission lines, is Z₁=Rₒₚₜ.

The load resistance is

$${R}_{L} = \frac{1}{n} {R}_{opt}$$

The characteristic impedance of the TLs decreases from Z₁ to

$$\frac{1}{( n - 1 )} {Z}_{1} ,$$

i.e. decreases from the first TL of the series connected transmission lines to the last TL of the series connected transmission lines, and the characteristic impedance of the last transmission line at the output is equal to

$$\frac{1}{( n - 1 )} {Z}_{1} = \frac{n}{( n - 1 )} {R}_{L} .$$

The transistor's optimal admittance Yₒₚₜ=1/Rₒₚₜ needs to be matched to the admittance difference of neighboring transmission lines:

$$\frac{1}{{R}_{opt}} = \frac{1}{{Z}_{i}} - \frac{1}{{Z}_{i - 1}} ( i = 1 , 2 , … , n - 1 ) \qquad ( 3 )$$

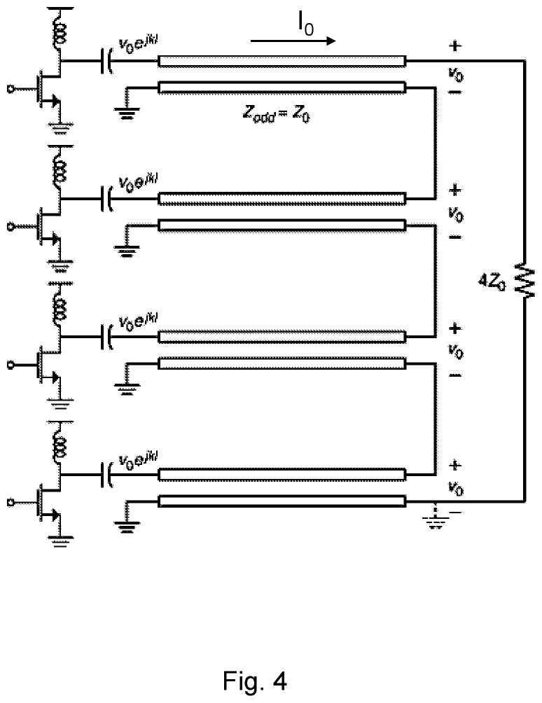

The outputs from power cells can also be combined by adding voltages, as shown in FIG. 4. If the coupled transmission lines have a coupling coefficient k approaching to 1, the coupled transmission line is dominated by odd mode. Such kind of coupled transmission lines are called as transmission-line transformer. The input port of the coupled TLs is a single-ended input connected to the outputs of the respective power cells and a voltage signal V₀ is generated at each output port of the coupled TLs indicted with + and − as shown in FIG. 4. The output ports of the coupled TLs are connected in series and the voltages V₀ generated by the power cells at the single-ended input ports are added in phase at the output ports of the coupled transmission lines.

The impedance at the output port is equal to sum of odd-mode characteristic impedance, nZ₀ₒ where n is the number of the coupled lines. In the implementation, two TLs should by tightly coupled, let even-mode characteristic impedance Z₀ₑ be very large and Z₀ₒ be very small. Moreover, the length of TLs should be as short as possible, to minimize the loss.

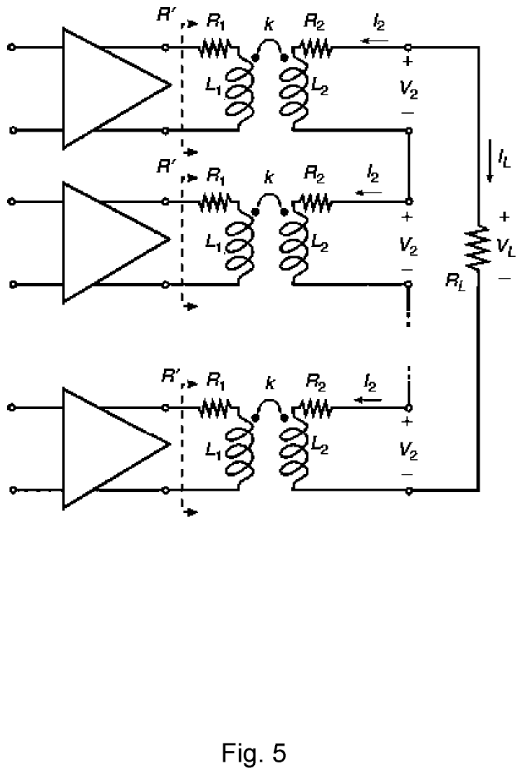

Similarly, for a transformer-based voltage combiner, as shown in FIG. 5, the voltage swing at the load, R_{L}, is the sum of the voltage swing of the secondary winding, and the current through R_{L} is equal to the current of the secondary winding.

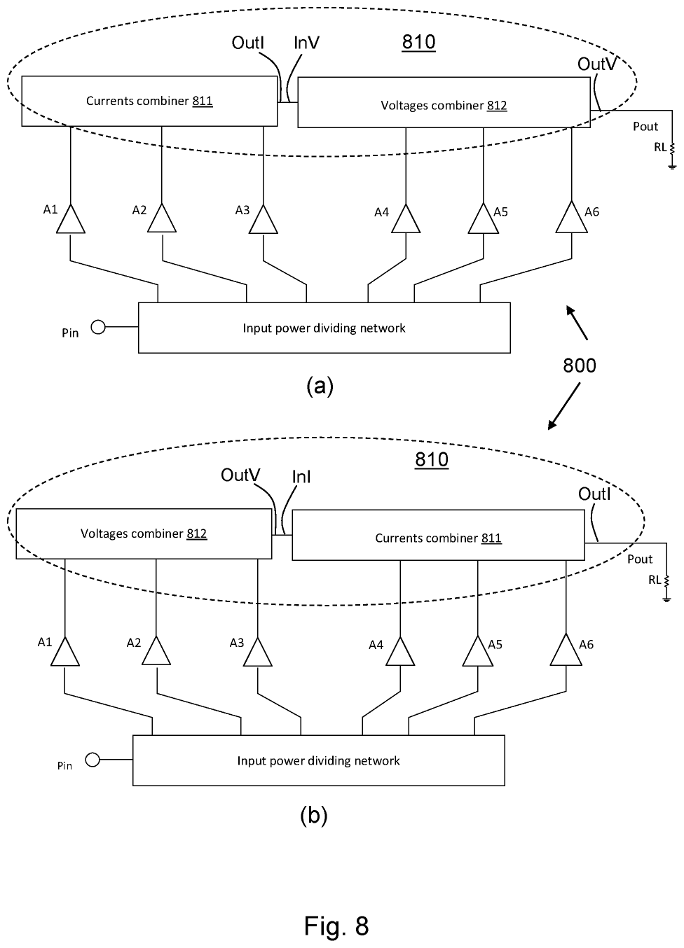

FIG. 8 (a) and FIG. 8 (b) each shows a schematic block diagram of a power amplifier 800. The power amplifier 800 comprises multiple power cells A1, A2, A3, A4, A5, A6 and a power combiner 810 according to embodiments herein for combing output powers from the multiple power cells A1, A2, A3, A4, A5, A6. The power combiner 810 comprises a current combiner 811 configured to combine output currents from at least two power cells A1, A2, A3 comprised in the power amplifier 800 and a voltage combiner 812 configured to combine output voltages from at least two power cells, A4, A5, A6 comprised in the power amplifier 800. The voltage combiner 812 and current combiner 811 are connected in cascade.

The voltage combiner 812 and current combiner 811 may be connected in cascade in different order. That is the voltage combiner 811 may be connected before or after the current combiner 811. Either the voltage combiner 812 or the current combiner 811 may be connected to a load R_{L} of the power amplifier 800.

When the voltage combiner 812 is connected after the current combiner 811, an input terminal InV of the voltage combiner 812 is connected to an output terminal OutI of the current combiner 811 and an output terminal OutV of the voltage combiner 812 is connected to the load R_{L} of the power amplifier 800, as shown in FIG. 8(a).

When the voltage combiner 812 is connected before the current combiner 811, an input terminal InI of the current combiner 811 is connected to an output terminal OutV of the voltage combiner 812 and an output terminal OutI of the current combiner 811 is connected to the load R_{L} of the power amplifier, as shown in FIG. 8 (b).

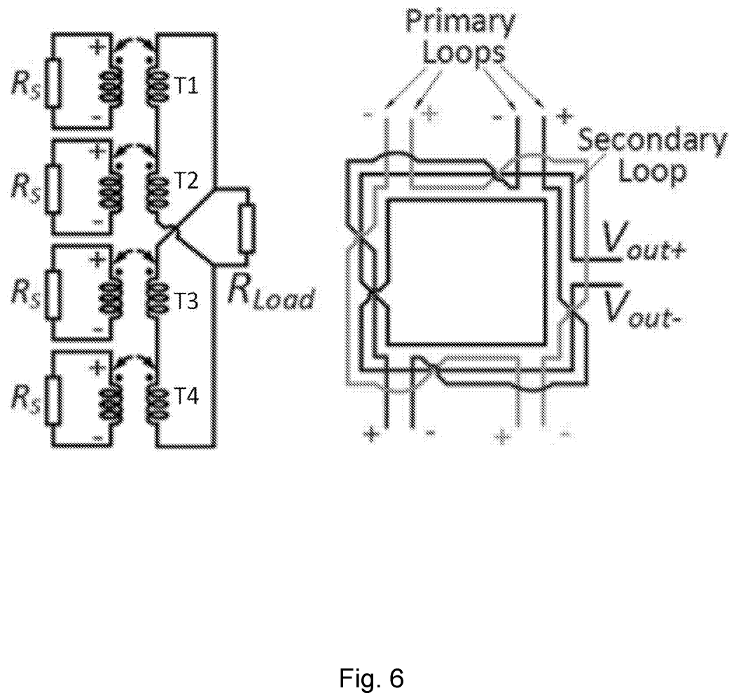

The proposed power combiner 810 with hybrid current and voltage combining differs from the hybrid one shown in FIG. 6, where the voltage combiner and current combiner are connected in parallel. Comparing with current combined by non-uniform TLs, the transformer based current combiner, i.e., connecting transformer in parallel, has high loss. In the power combiner 810 according to embodiments herein, the voltage combiner 812 and current combiner 811 are connected in cascade.

The current combiner 811 may comprise one or more transmission lines connected in series and the voltage combiner 812 may comprises one or more transformer or coupled transmission lines. Each transformer or coupled transmission line comprises a primary transmission line and a secondary transmission line.

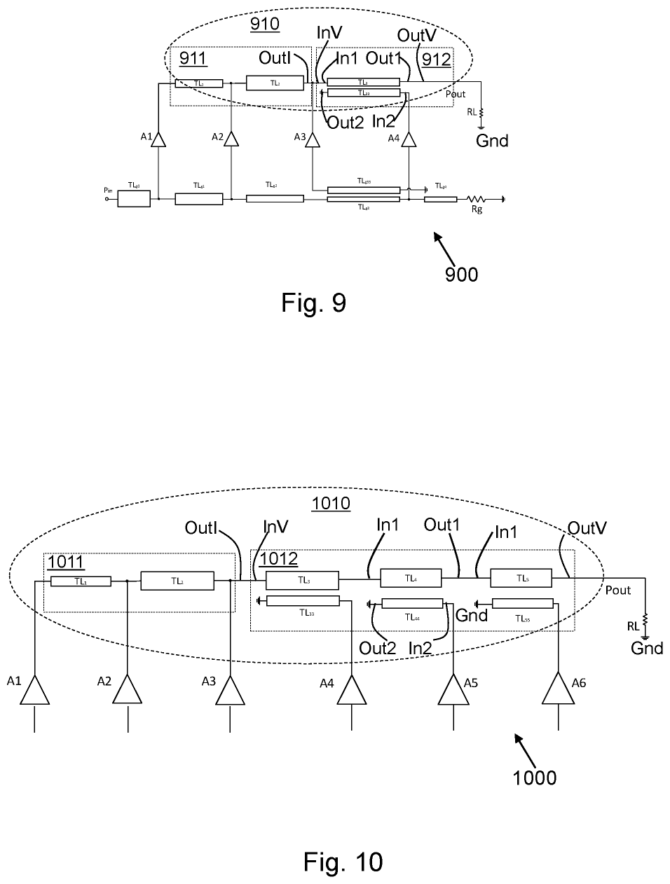

FIG. 9 shows an example embodiment of a power combiner 910 according to embodiments herein comprised in a power amplifier 900. The power combiner 910 comprises a current combiner 911 comprising two transmission lines TL₁, TL₂ connected in series and output terminals of the power cells A₁, A₂, A₃ comprised in the power amplifier 900 for current combining are connected to the transmission lines TL₁, TL₂.

The power combiner 910 comprises a voltage combiner 912 comprising a transformer or coupled transmission line TL₃/TL₃₃ comprising a primary transmission line TL₃ having a first input terminal In1 and a first output terminal Out1 and a secondary transmission line TL₃₃ having a second input terminal In2 and a second output terminal Out2. The first output terminal Out1 of the primary transmission line TL₃ is the output terminal OutV of the voltage combiner 912 and is connected to the load R_{L} of the power amplifier 900.

The voltage combiner according to embodiment herein may comprises two or more transformer or coupled transmission lines connected in series.

FIG. 10 shows an example embodiment of a power combiner 1010 according to embodiments herein comprised in a power amplifier 1000. The power combiner 1010 comprises a current combiner 1011 comprising two transmission lines TL₁, TL₂ connected in series and output terminals of the power cells A₁, A₂, A₃ comprised in the power amplifier 1000 for current combining are connected to the transmission lines TL₁, TL₂.

The power combiner 1010 comprises three transformer or coupled transmission lines TL₃/TL₃₃, TL₄/TL₄₄, TL₅/TL₅₅. Each transformer or coupled transmission line comprises a primary transmission line TL₃, TL₄, TL₅ having a first input terminal In1 and a first output terminal Out1 and a secondary transmission line TL₃₃, TL₄₄, TL₅₅ having a second input terminal In2 and a second output terminal Out2.

The transformer or coupled transmission lines TL₃/TL₃₃, TL₄/TL₄₄, TL₅/TL₅₅ in the voltage combiner 1012 are connected in series such that the first output terminal Out1 of the primary transmission line in a proceeding transformer or coupled transmission line e.g. TL₄ is connected to the first input terminal In1 of the primary transmission line in the next transformer or coupled transmission line e.g. TL₅.

The first input terminal In1 of the primary transmission line TL₃ in the first transformer or coupled transmission line TL₃/TL₃₃ is the input terminal InV of the voltage combiner 1012.

The first output terminal Out1 of the primary transmission line TL₅ in the last transformer or coupled transmission line TL₅/TL₅₅ is the output terminal OutV of the voltage combiner 1012 to connect to R_{L}, the load of the power amplifier.

The second input terminals In2 of the secondary transmission lines TL₃₃, TL₄₄, TL₅₅ are connected to output terminals of the respective power cells A₄, A₅, A₆ for voltage combining.

The second output terminals Out2 of the secondary transmission lines TL₃₃, TL₄₄, TL₅₅ are connected to a signal ground Gnd.

The voltage combiner according to embodiment herein may comprises two or more transformer or coupled transmission lines connected in cascade.

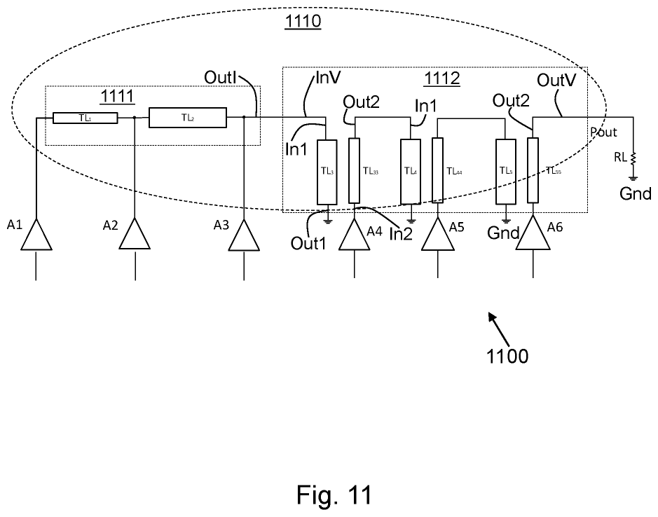

FIG. 11 shows an example embodiment of a power combiner 1110 according to embodiments herein comprised in a power amplifier 1100. The power combiner 1110 comprises a current combiner 1111 comprising two transmission lines TL₁, TL₂ connected in series and output terminals of the power cells A₁, A₂, A₃ comprised in the power amplifier 1100 for current combining are connected to the transmission lines TL₁, TL₂.

The power combiner 1110 comprises a voltage combiner 1112 comprising three transformer or coupled transmission lines TL₃/TL₃₃, TL₄/TL₄₄, TL₅/TL₅₅, which may also be referred to as transmission-line-transformer. Each transformer or coupled transmission line comprises a primary transmission line TL₃, TL₄, TL₅ having a first input terminal In1 and a first output terminal Out1 and a secondary transmission line TL₃₃, TL₄₄, TL₅₅ having a second input terminal In2 and a second output terminal Out2.

The transformer or coupled transmission lines TL₃/TL₃₃, TL₄/TL₄₄, TL₅/TL₅₅ in the voltage combiner 1112 are connected in cascade such that the second output terminal Out2 of the secondary transmission line in a proceeding transformer or coupled transmission line e.g. TL₃₃ is connected to the first input terminal In1 of the primary transmission line in the next transformer or coupled transmission line e.g. TL₄.

The first input terminal In1 of the primary transmission line TL₃ in the first transformer or coupled transmission line TL₃/TL₃₃ is the input terminal InV of the voltage combiner 1112.

The second output terminal Out2 of the secondary transmission line TL₅₅ in the last transformer or coupled transmission line TL₅/TL₅₅ is the output terminal OutV of the voltage combiner 1112 to connect to R_{L}, the load of the power amplifier.

The second input terminals In2 of the secondary transmission lines TL₃₃, TL₄₄, TL₅₅ are connected to output terminals of the respective power cells A₄, A₅, A₆ for voltage combining.

The first output terminals Out1 of the primary transmission lines TL₃, TL₄, TL₅ are connected to a signal ground Gnd.

The voltage combiner may comprise two or more transformer or coupled transmission lines connected in series and two or more transformer or coupled lines connected in cascade.

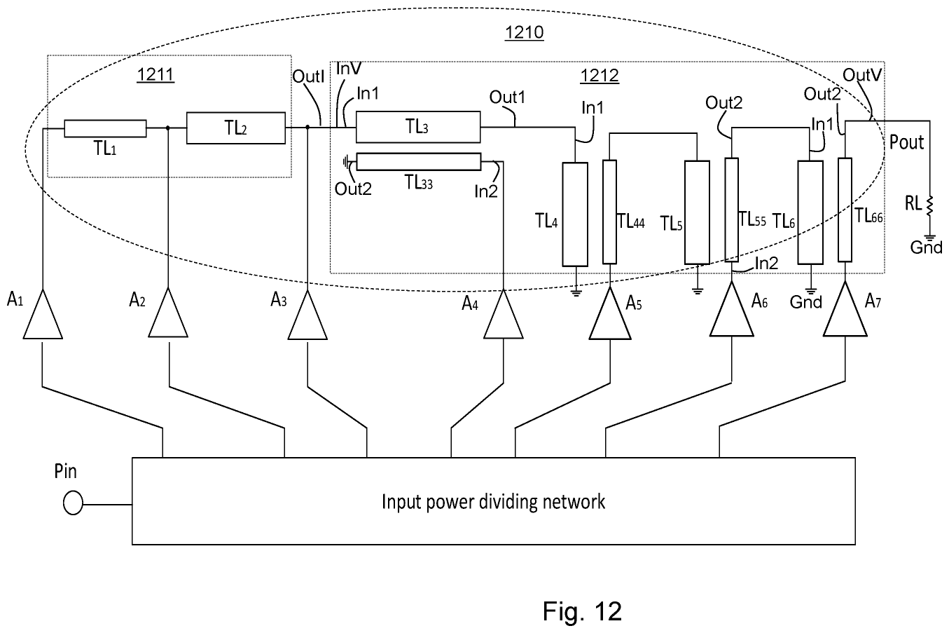

FIG. 12 shows an example embodiment of a power combiner 1210 according to embodiments herein comprised in a power amplifier 1200. The power combiner 1210 comprises a current combiner 1211 comprising two transmission lines TL₁, TL₂ connected in series and output terminals of the power cells A₁, A₂, A₃ comprised in the power amplifier 1200 for current combining are connected to the transmission lines TL₁, TL₂.

The power combiner 1210 comprises a voltage combiner 1212 comprising four transformer or coupled transmission lines TL₃/TL₃₃, TL₄/TL₄₄, TL₅/TL₅₅, TL₆/TL₆₆. Each transformer/coupled transmission line or transmission-line-transformer comprises a primary transmission line TL₃, TL₄, TL₅ TL₆ having a first input terminal In1 and a first output terminal Out1 and a secondary transmission line TL₃₃, TL₄₄, TL₅₅, TL₆₆ having a second input terminal In2 and a second output terminal Out2.

In the voltage combiner 1212, at least two transformer or coupled transmission lines e.g. TL₃/TL₃₃ TL₄/TL₄₄ are connected in series such that the first output terminal Out1 of the primary transmission line e.g. TL₃ in a proceeding transformer or coupled transmission line is connected to the first input terminal In1 of the primary transmission line e.g. TL₄ in the next transformer or coupled transmission line. At least two transformer or coupled transmission lines e.g. TL₄/TL₄₄, TL₅/TL₅₅, TL₆/TL₆₆ are connected in cascade such that the second output terminal Out2 of the secondary transmission line e.g. TL₅₅ in a proceeding transformer or coupled transmission line is connected to the first input terminal In1 of the primary transmission line e.g. TL₆ in the next transformer or coupled transmission line.

The first input terminal In1 of the primary transmission line TL₃ in the first transformer or coupled transmission line TL₃/TL₃₃ is the input terminal InV of the voltage combiner 1212 to connect to the output terminal OutI of the current combiner 1211.

The second output terminal Out2 of the secondary transmission line TL₆₆ in the last transformer or coupled transmission line e.g. TL₆/TL₆₆ is the output terminal OutV of the voltage combiner 1212 to connect to R_{L}, the load of power amplifier

The second input terminals In2 of the secondary transmission lines TL₃₃, TL₄₄, TL₅₅, TL₆₆ are connected to output terminals of the respective power cells A₄, A₅, A₆, A₇ for voltage combining.

The first output terminals Out1 of the primary transmission line e.g. TL₄. TL₅, TL& in the cascade connected coupled transmission lines TL₄/TL₄₄, TL₅/TL₅₅, TL₆/TL₆₆ and a second output terminal Out2 of the secondary transmission line e.g. TL₃₃ in the series connected coupled lines TL₃/TL₃₃ TL₄/TL₄₄ are connected to a signal ground Gnd.

To demonstrate the performance and advantages of the power combiner 910, 1010, 1210 according to embodiments herein, the power amplifier 900 with power cells distributed along the non-uniform transmission lines shown in FIG. 9 has been implemented and simulated. A conventional non-uniform distributed amplifier with only current combining is shown in FIG. 13, where the characteristic impedances of the transmission lines at drains of the power cells, i.e. from TL₁ to TL₃ decrease, correspondingly, the widths of TL₁ to TL₃ increase, which are e.g. 67 μm, 105 μm, and 300 μm accordingly.

The power combiner 910 comprises a current combiner 911 with transmission lines TL₁ and TL₂ and a voltage combiner 912 with a coupled transmission lines TL₃/TL₃₃ form a hybrid power combiner. Comparing to the conventional non-uniform distributed amplifier, a wide width transmission line TL₃ with 300 μm is replaced by the coupled TLs i.e. TL₃/TL₃₃. TL₃ and TL₃₃ have the same width equal to 70 μm, a separation of the two transmission lines is 2 μm. The total width of the coupled transmission lines is 142 μm.

As expected, the voltage combiner TL₃/TL₃₃ boosts the output impedance. In this case, the output impedance of the power amplifier is increased from 10.7Ω for the conventional distributed amplifier to 18.3Ω for the power amplifier 900 with the hybrid power combiner 910 without degrading the performance regarding gain, the maximum output power and the maximum Power-added efficiency (PAE).

For the power amplifier 1000, 1100 shown in FIGS. 10 and 11 with 6 power cells, the output impedance of the power combiner is 35.5Ω. A conventional distributed power amplifier with 6 power cells, the output impedance of the last power cell could be lower than 10Ω, when the output power reaches 40 dBm, and the fundamental voltage amplitude is 12 V. It is very difficult to implement a TL with such a low characteristic impedance to match the output impedance of the last power cell in a monolithic millimeter wave integrated circuit.

Therefore, it has been demonstrated that the proposed hybrid power combiner 910, 1010, 1110 can solve issues with too wide width TLs used in a conventional distributed amplifier or a distributed efficient power amplifier (DEPA) and too low output impedance without degrading the bandwidth of the whole power amplifier significantly.

To summarize, the power combiner 810, 910, 1010, 1110, 1210 according to embodiments herein comprises a current combiner 811, 911, 1011, 1111, 1211 and a voltage combiner 812, 912, 1012, 1112, 1212 and can solve the problem of a distributed power amplifier. Namely, the number of power cells could be limited by the difficulty of implementation of a transmission line with extra low characteristic impedance. While the voltage combiner 812, 912, 1012, 1112, 1212 in the power combiner 810, 910, 1010, 1110, 1210 according to embodiments herein needs not TLs with low characteristic impedances.

The current combiner and voltage combiner are connected in cascade. That is one terminal of the voltage combiner 812, 912, 1012, 1112, 1212 may be connected to the current combiner, and another terminal may be connected to the load of a power amplifier. In this way, the voltage combiner 812, 912, 1012, 1112, 1212 acts as an upward impedance transformer and converts up the output impedance of the current combiner, so an ITN can be removed if the output impedance of the voltage combiner 812, 912, 1012, 1112, 1212 reaches 50Ω.

When the output impedance of the voltage combiner 812, 912, 1012, 1112, 1212 does not reach 50Ω, an ITN is still needed. However, the voltage combiner 812, 912, 1012, 1112, 1212 has benefits of boosting output impedance so the impedance transformation ratio to 50Ω is reduced. Consequently, the number of TLs to build an ITN is reduced, thus, the loss of the ITN can be reduced.

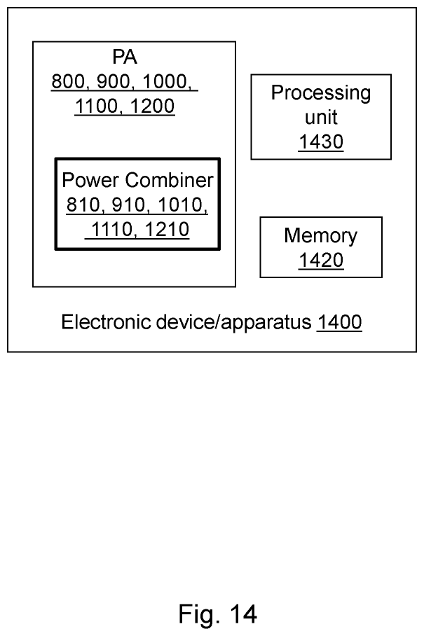

The power combiner 810, 910, 1010, 1110, 1210 according to embodiments herein may be employed in various power amplifiers, electronic devices or apparatus etc. FIG. 14 shows a block diagram for an electronic device or apparatus 1400. The electronic device or apparatus 1400 comprises a power amplifier 900, 1000, 1100, 1200 comprising a power combiner 810, 910, 1010, 1110, 1210 according to embodiments herein. The electronic device 1400 may be a transmitter, a transceiver, a base station, a mobile device, a user equipment, a wireless communication device, a radar. The electronic device 1400 may comprise other units, where a memory 1420, a processing unit 1430 are shown.

The embodiments herein are not limited to the above described preferred embodiments. Various alternatives, modifications and equivalents may be used. When using the word “comprise” or “comprising” it shall be interpreted as non-limiting, i.e. meaning “consist at least of”. Therefore, the above embodiments should not be taken as limiting the scope of the invention, which is defined by the appended claims.

1. A power combiner for combining output powers from multiple power cells comprised in a power amplifier, the power combiner comprising:
a current combiner configured to combine output currents from at least two power cells comprised in the power amplifier;
a voltage combiner configured to combine output voltages from at least two power cells comprised in the power amplifier; and
the voltage combiner and current combiner being connected in cascade.

2. The power combiner according to claim 1, wherein:
an input terminal of the voltage combiner is connected to an output terminal of the current combiner and an output terminal of the voltage combiner is connected to a load of the power amplifier; or
an input terminal of the current combiner is connected to an output terminal of the voltage combiner and an output terminal of the current combiner is connected to a load of the power amplifier.

3. The power combiner according to claim 1, wherein the current combiner comprises one or more transmission lines connected in series and output terminals of the at least two power cells for current combining are connected to the transmission lines.

4. The power combiner, wherein the voltage combiner comprises one or more transformer or coupled transmission lines, and wherein each transformer or coupled transmission line comprises a primary transmission line having a first input terminal and a first output terminal and a secondary transmission line having a second input terminal and a second output terminal.

5. The power combiner according to claim 4, wherein the voltage combiner comprises two or more transformer or coupled transmission lines connected in series such that the first output terminal of the primary transmission line in a proceeding transformer or coupled transmission line is connected to the first input terminal of the primary transmission line in the next transformer or coupled transmission line; and wherein:
the first input terminal of the primary transmission line in the first transformer or coupled transmission line is the input terminal of the voltage combiner;
the first output terminal of the primary transmission line in the last transformer or coupled transmission line is the output terminal of the voltage combiner;
the second input terminals of the secondary transmission lines are connected to output terminals of the respective power cells for voltage combining; and
the second output terminals of the secondary transmission lines are connected to a signal ground.

6. The power combiner according to claim 4, wherein the voltage combiner comprises two or more transformer or coupled transmission lines connected in cascade such that the second output terminal of the secondary transmission line in a proceeding transformer or coupled transmission line is connected to the first input terminal of the primary transmission line in the next transformer or coupled transmission line; and wherein:
the first input terminal of the primary transmission line in the first transformer or coupled transmission line is the input terminal of the voltage combiner;
the second output terminal of the secondary transmission line in the last transformer or coupled transmission line is the output terminal of the voltage combiner;
the second input terminals of the secondary transmission lines are connected to output terminals of the respective power cells for voltage combining; and
the first output terminals of the primary transmission lines are connected to a signal ground.

7. The power combiner according to claim 4, wherein the voltage combiner comprises two or more transformer or coupled transmission lines, and wherein:
at least two coupled transmission lines are connected in series such that the first output terminal of the primary transmission line in a proceeding transformer or coupled transmission line is connected to the first input terminal of the primary transmission line in the next transformer or coupled transmission line; and
at least two coupled transmission lines are connected in cascade such that the second output terminal of the secondary transmission line in a proceeding transformer or coupled transmission line is connected to the first input terminal of the primary transmission line in the next transformer or coupled transmission line; and wherein:
the first input terminal of the primary transmission line in the first transformer or coupled transmission line is the input terminal of the voltage combiner;
the second output terminal of the secondary transmission line in the last transformer or coupled transmission line is the output terminal of the voltage combiner;
the second input terminals of the secondary transmission lines are connected to output terminals of the respective power cells for voltage combining;
the first output terminals of the primary transmission line in the cascade connected coupled transmission lines and a second output terminal of the secondary transmission line in the series connected coupled lines are connected to a signal ground.

8. A power amplifier comprising a power combiner, the power combiner for combining output powers from multiple power cells comprised in the power amplifier, the power combiner comprising:
a current combiner configured to combine output currents from at least two power cells comprised in the power amplifier;
a voltage combiner configured to combine output voltages from at least two power cells comprised in the power amplifier; and
the voltage combiner and current combiner being connected in cascade.

9. An electronic device comprising a power amplifier, the power amplifier comprising a power combiner, the power combiner for combining output powers from multiple power cells comprised in the power amplifier, the power combiner comprising:
a current combiner configured to combine output currents from at least two power cells comprised in the power amplifier;
a voltage combiner configured to combine output voltages from at least two power cells comprised in the power amplifier; and
the voltage combiner and current combiner being connected in cascade.

10. The electronic device according to claim 9, wherein the electronic device is any one of a transmitter, a transceiver, a base station, a mobile device, a user equipment, a radar, a wireless communication device for a communication system.

11. The power combiner according to claim 2, wherein the current combiner comprises one or more transmission lines connected in series and output terminals of the at least two power cells for current combining are connected to the transmission lines.

12. The power combiner according to claim 2, wherein the voltage combiner comprises one or more transformer or coupled transmission lines, and wherein each transformer or coupled transmission line comprises a primary transmission line having a first input terminal and a first output terminal and a secondary transmission line having a second input terminal and a second output terminal.

13. The power combiner according to claim 12, wherein the voltage combiner comprises two or more transformer or coupled transmission lines connected in series such that the first output terminal of the primary transmission line in a proceeding transformer or coupled transmission line is connected to the first input terminal of the primary transmission line in the next transformer or coupled transmission line; and wherein:
the first input terminal of the primary transmission line in the first transformer or coupled transmission line is the input terminal of the voltage combiner;
the first output terminal of the primary transmission line in the last transformer or coupled transmission line is the output terminal of the voltage combiner;
the second input terminals of the secondary transmission lines are connected to output terminals of the respective power cells for voltage combining; and
the second output terminals of the secondary transmission lines are connected to a signal ground.

14. The power combiner according to claim 12, wherein the voltage combiner comprises two or more transformer or coupled transmission lines connected in cascade such that the second output terminal of the secondary transmission line in a proceeding transformer or coupled transmission line is connected to the first input terminal of the primary transmission line in the next transformer or coupled transmission line; and wherein:
the first input terminal of the primary transmission line in the first transformer or coupled transmission line is the input terminal of the voltage combiner;
the second output terminal of the secondary transmission line in the last transformer or coupled transmission line is the output terminal of the voltage combiner;
the second input terminals of the secondary transmission lines are connected to output terminals of the respective power cells for voltage combining; and
the first output terminals of the primary transmission lines are connected to a signal ground.

15. The power amplifier according to claim 8, wherein:
an input terminal of the voltage combiner is connected to an output terminal of the current combiner and an output terminal of the voltage combiner is connected to a load of the power amplifier; or
an input terminal of the current combiner is connected to an output terminal of the voltage combiner and an output terminal of the current combiner is connected to a load of the power amplifier.

16. The power amplifier according to claim 8, wherein the current combiner comprises one or more transmission lines connected in series and output terminals of the at least two power cells for current combining are connected to the transmission lines.

17. The power amplifier according to claim 8, wherein the voltage combiner comprises one or more transformer or coupled transmission lines, and wherein each transformer or coupled transmission line comprises a primary transmission line having a first input terminal and a first output terminal and a secondary transmission line having a second input terminal and a second output terminal.

18. The power amplifier according to claim 17, wherein the voltage combiner comprises two or more transformer or coupled transmission lines connected in series such that the first output terminal of the primary transmission line in a proceeding transformer or coupled transmission line is connected to the first input terminal of the primary transmission line in the next transformer or coupled transmission line; and wherein:
the first input terminal of the primary transmission line in the first transformer or coupled transmission line is the input terminal of the voltage combiner;
the first output terminal of the primary transmission line in the last transformer or coupled transmission line is the output terminal of the voltage combiner;
the second input terminals of the secondary transmission lines are connected to output terminals of the respective power cells for voltage combining; and
the second output terminals of the secondary transmission lines are connected to a signal ground.

19. The power amplifier according to claim 17, wherein the voltage combiner comprises two or more transformer or coupled transmission lines connected in cascade such that the second output terminal of the secondary transmission line in a proceeding transformer or coupled transmission line is connected to the first input terminal of the primary transmission line in the next transformer or coupled transmission line; and wherein:
the first input terminal of the primary transmission line in the first transformer or coupled transmission line is the input terminal of the voltage combiner;
the second output terminal of the secondary transmission line in the last transformer or coupled transmission line is the output terminal of the voltage combiner;
the second input terminals of the secondary transmission lines are connected to output terminals of the respective power cells for voltage combining; and
the first output terminals of the primary transmission lines are connected to a signal ground.

20. The power amplifier according to claim 17, wherein the voltage combiner comprises two or more transformer or coupled transmission lines, and wherein:
at least two coupled transmission lines are connected in series such that the first output terminal of the primary transmission line in a proceeding transformer or coupled transmission line is connected to the first input terminal of the primary transmission line in the next transformer or coupled transmission line; and
at least two coupled transmission lines are connected in cascade such that the second output terminal of the secondary transmission line in a proceeding transformer or coupled transmission line is connected to the first input terminal of the primary transmission line in the next transformer or coupled transmission line; and wherein:
the first input terminal of the primary transmission line in the first transformer or coupled transmission line is the input terminal of the voltage combiner;
the second output terminal of the secondary transmission line in the last transformer or coupled transmission line is the output terminal of the voltage combiner;
the second input terminals of the secondary transmission lines are connected to output terminals of the respective power cells for voltage combining;
the first output terminals of the primary transmission line in the cascade connected coupled transmission lines and a second output terminal of the secondary transmission line in the series connected coupled lines are connected to a signal ground.
